(19) United States
(12) Patent Application Publication
(10) Pub. No.: US 2022/0059426 A1
(43) Pub. Date: Feb. 24, 2022

(54) METHOD FOR PRODUCING A POWER MODULE UNIT, POWER MODULE UNIT, NETWORK PART AND FREQUENCY CONVERTER

(71) Applicant: Siemens Aktiengesellschaft, 80333 München (DE)

(72) Inventors: DANIEL KAPPAUF, Gräfenberg (DE); STANISLAV PANICERSKI, Nürnberg (DE); JENS SCHMENGER, Forchheim (DE); ROBERT GOSPOS, Buckenhof (DE); CHRISTIAN KNEUER, Fürth (DE); MATTHIAS NÄHRIG, Höchstadt an der Aisch, Bayern (DE)

(73) Assignee: Siemens Aktiengesellschaft, 80333 München (DE)

(21) Appl. No.: 17/275,621

(22) PCT Filed: Jul. 3, 2019
(86) PCT No.: PCT/EP2019/067881

§ 371 Date: Mar. 11, 2021

(30) Foreign Application Priority Data
Sep. 12, 2018 (EP) 18194020.6

(51) Int. Cl. H01L 23/367; H01L 23/373; H01L 21/48

(52) U.S. Cl. CPC H01L 23/3672; H01L 21/4882; H01L 23/3736

(57) ABSTRACT

A power module unit, in particular for a frequency converter, includes a base plate having a first side provided with a recess and a second side, a cooling fin fastened in the recess of the base plate at least in one region by a positive fit, a material fit, and/or a non-positive fit, and a substrate provided for a power semiconductor and disposed on the second side of the base plate.

The invention relates to a method for producing a power module unit and to a power module unit. Moreover, the invention relates to a power supply (network part) and to a frequency converter.

As a rule, power modules comprise a substrate with a power semiconductor, for example an IGBT (insulated gate bipolar transistor), which is connected to a substrate in a fixed manner. The substrate has a metal structure on both sides, wherein the metal structure is embodied for connecting to the power semiconductor on the one side and can be fastened to a base plate on the other side.

According to the current prior art, a thermally conductive structure is preferably applied to the base plate, which is fastened to a heat sink. In order to offset thermal effects, a complex prebending of the base plate is necessary, in order for the base plate to be connected to the heat sink in a fixed manner even at a temperature of more than 100 degrees Celsius.

The unit, comprising a power module and a heat sink, is referred to here as a power module unit.

A further disadvantage of the prior art is the large number of material transitions. This reduces a flow of heat which starts from the power semiconductor and is transferred over the base plate to the heat sink.

In order to improve the transfer of heat from the power semiconductor to the heat sink, DE 10 2013 207 804 A1 for example proposes to embody a base plate with thermally conductive structures in an integral manner on the one side. The power semiconductor is fastened on the opposite side of the base plate.

The size of the thermally conductive structures, however, is limited due to the production. Moreover, the production of such a power module unit is elaborate and therefore expensive.

It is thus the object of the invention to simplify the method for producing a power module unit.

The object is achieved by a power module unit as claimed in claim 1. The object is further achieved by a frequency converter or a power supply as claimed in claim 10. Moreover, the object is achieved by a method as claimed in claim 11.

Advantageous embodiments and developments are the subject matter of the dependent claims.

The invention is based on the knowledge that a direct attachment of the substrate with the power semiconductor to the base plate replaces a material border between the base plate and the heat sink. Preferably, the substrate is fastened to the base plate of the heat sink by a soldered connection. The base plate therefore serves as a carrier for the substrate on the first side. Furthermore, the second side of the base plate serves to fasten the cooling fins.

In conventional heat sinks with cooling fins, which may be several centimeters long, this method leads to difficulties, because the entire heat sink has to be heated to a temperature of approx. 200 to approx. 500 degrees Celsius in a furnace for example. However, heating the entire heat sink expends a lot of energy and is time-consuming. Accordingly, the invention is based on the insight that it is advantageous to merely heat the base plate with the substrate in the furnace and to fasten the cooling fins after the substrate has been fastened in recesses in the base plate. The fastening of the cooling fins preferably takes place in such a manner that the base plate with the substrate is not bent. A bending of the base plate could damage the substrate.

This is achieved by a trapezoid-shaped cross-section of the recess by way of example. Moreover, the cooling fins advantageously may be introduced into the respective recess in the tangential direction in relation to the first side.

The substrate preferably comprises a ceramic layer, wherein the ceramic layer has a metal layer, at least in regions, on the top side and the bottom side in each case. The metal layer preferably comprises copper, silver or tin. The metal layer, preferably applied in regions, on the top side of the substrate serves to fasten the power semiconductor. The metal layer preferably applied on the bottom side serves for the soldered, pressed or sintered connection of the substrate to the base plate.

The power module unit has a base plate with at least one recess on a first side, wherein at least one cooling fin is fastened in the respective recess, wherein the respective cooling fin is fastened in each case in a recess of the base plate by a connection that is designed with a positive fit at least in regions, a material fit in regions and/or a non-positive fit in regions, wherein the base plate has a substrate for a power semiconductor on a second side.

The power module unit optionally also comprises a housing which protects the substrate from environmental influences. The substrate serves as a base for power semiconductors such as an IGBT or a thyristor. It is also possible for a plurality of power semiconductors to be fastened to the substrate.

The recess preferably runs along the first side from one end of the base plate to the other end of the base plate.

The recess advantageously serves to accommodate one or more cooling fins. The respective cooling fin is preferably introduced into the recess in the base plate when the substrate on the second side is already fastened to the base plate.

Preferably, the power module unit additionally comprises a housing, wherein the housing covers the second side, at least in regions. The housing serves to cover and therefore to protect the substrate or the at least one power semiconductor.

A material connection is understood, by way of example, to mean a soldered connection, an adhesive connection or a welded connection.

The connection of the cooling fin to the base plate is preferably designed with a positive fit, at least in regions. The positive connection establishes a good thermal connection between the base plate and the respective cooling fin. The positive connection accordingly serves for the improved dissipation of waste heat of the power semiconductors to the cooling fins via the base plate.

Preferably, the cooling fins are fastened to the base plate by way of a non-positive connection in such a manner that the cooling fins are inserted into a heated base plate and enter a non-positive connection as the base plate cools down. As an alternative or in addition, the cooling fins may also be cooled when being introduced and embody a non-positive connection by heating to room temperature.

The invention discloses the following advantages:

By way of a direct connection of the substrate to the base plate and only one further thermal resistance in relation to the cooling fins, the heat can be dissipated from the substrate via the cooling fins in a particularly efficient manner.

By way of the variable connection of the base plate to the cooling fins, parameters of the respective cooling fin such as length, shape and surface finish can be adapted to the application of the power module unit in a targeted manner.

Due to the substrate only being fastened to the base plate, it can be produced in a rapid and energy-saving manner with the aid of a furnace.

In an advantageous embodiment of the invention, the respective cooling fin is connected to the base plate by way of a pressed connection, an adhesive connection or a soldered connection.

As an alternative or in addition, the respective cooling fin may be fastened in the recess in the base plate by a soldered connection or an adhesive connection.

By way of a fixed connection of the respective cooling fin to the base plate, the power module unit is embodied as stable against external influences, in addition, due to a fixed connection of the respective cooling fin to the base plate, an effective and secure transfer of heat from the power semiconductor to the cooling fins is ensured.

In a further advantageous embodiment of the invention, the base plate has copper, aluminum or a layer of copper and a layer of aluminum.

Preferably, copper serves as a material for accommodating the substrate, because it is well suited for building a soldered connection and is an effective thermal conductor.

Preferably, aluminum serves as a material for the base plate, because aluminum on the one hand is an effective thermal conductor and moreover is suitable for a positive connection of the base plate to the cooling fins due to its effective deformability,

Particularly advantageously, the base plate is embodied from two metal layers connected onto one another in a fixed manner. Such a base pate has an aluminum layer adjoining the first side that has a copper layer on its top side. By way of example, both metal layers are connected to one another in a fixed manner by a rolling method. Alternatively, the layers may also be connected to one another by a soldering method, in particular using a high-temperature soldering method.

Such a layer has the advantages mentioned above and is commercially available.

In a further advantageous embodiment of the invention, the respective cooling fin has an attachment on at least one side, wherein the attachment touches the first side of the base plate once the cooling fin has been introduced.

The attachment serves to limit the penetration of the cooling fin into the recess in such a manner that a bottom side of the recess only touches the cooling fin.

As an alternative or in addition, the attachment may protrude into the recess in regions. By way of example, the recess has obliquely oriented side areas at its edges with the first side. The side areas serve to accommodate the skies area of the attachment which is likewise designed in an oblique manner.

By way of the attachment, it is possible to reduce strain on the base plate when introducing the respective cooling fin into the recess. In particular, the bending stress induced by a force perpendicular to the first side of the base plate can be effectively reduced. Reducing the force and therefore the bending stress on the base plate causes less strain on the connection of the substrate to the base plate when the cooling fins are introduced into the recess.

In a further advantageous embodiment of the invention, the respective cooling fin has copper, aluminum or an alloy.

The cooling fin is preferably embodied from a material with effective thermal conduction, in particular aluminum, an aluminum alloy, copper or a copper alloy.

By way of a material with effective thermal conductivity, the heat can be dissipated from the base plate efficiently.

In a further advantageous embodiment of the invention, the fastening of the base plate to the respective cooling fin is reinforced by notches and protrusions.

Preferably, at least some of the recesses in the base plate and/or the cooling fins have notches and/or protrusions. The recesses may imprint notches into the cooling fin when introducing the cooling fin into the respective recess. A positive connection is embodied by way of the notches, at least in regions.

Preferably, protrusions of the cooling fin protrude into notches of the respective recess. This enables a particularly fixed connection.

The protrusions in the respective recess accordingly serve for the improved connection of the cooling fins to the base plate.

In a further advantageous embodiment of the invention, the hardness of the material for the base plate and the hardness of the material for the respective cooling fin are different.

Preferably, the base plate has a material with a greater hardness than the material of the cooling fins. Thus, the material of the cooling fin is easily deformed and a positive connection between the base plate and the cooling fin is embodied, at least in regions.

In the alternative given above, the cooling fin and/or the inner side of the recess in the base plate are advantageously easily deformed when introducing the cooling fin into the respective recess. In particular, protrusions contribute to a deformation of the cooling fin and/or to the deformation of the base plate.

Alternatively, the material of the cooling fin may also be embodied as harder than the material of the base plate. Such an embodiment preferably leads to a simplified production of the power module unit.

In a further advantageous embodiment of the invention, the respective cooling fin is embodied in a U-shaped, O-shaped or 8-shaped manner.

Preferably, the cooling fin has an opening. The opening preferably serves to pass a cooling medium through, such as a flow of air. Preferably, the opening is embodied such that a cross-section of the cooling fin is internally hollow. Preferably, the cross-section of the respective cooling fin is accordingly embodied in an O-shaped manner.

Preferably, the cooling fin is embodied with a reinforcement in the center, in particular a material transition.

This material transition leads to an 8-shaped cross-section of the cooling fin.

In a further advantageous embodiment of the invention, a cross-section of the respective recess is tapered toward the second side, preferably in a trapezoid-shaped manner.

In order to only transfer a minimal bending stress to the base plate when introducing the respective cooling fin, the recess is embodied as tapered toward the inside. The recess is preferably embodied in a trapezoid-shaped manner. Protrusions are positioned on the sides of the inner area of the respective recesses, as appropriate. The protrusions preferably serve to fix the cooling fin in the recess.

Due to the inwardly tapered recess, the substrate of the power module unit is advantageously protected when introducing the respective cooling fin.

hi a further advantageous embodiment of the invention, further cooling fins are positioned between the cooling fins, wherein the respective further cooling fin and the cooling fin only overlap at the sides in regions.

The further cooling fins are preferably connected to the cooling fins with a non-positive fit. The further cooling fins and the cooling fins preferably overlap with a width of 1 centimeter to 2 centimeters in each case.

Preferably, the sides of the cooling fins are embodied with a corrugated structure, at least hi the region in which the cooling fins and the further cooling fins overlap in each case. A corrugated structure is understood in particular to mean that the side of the respective cooling fin and/or the side of the respective further cooling fin have protrusions. The protrusion may have a triangular cross-section. Preferably, the protrusions are oriented in parallel with one another in each case.

Advantageously, the protrusions are oriented in parallel with the edge of the cooling fin in each case.

Preferably, notches are positioned between the protrusions in each case. Preferably, the notches have a triangular cross-section.

Preferably, the protrusions of the cooling fin protrude into the notches of the further cooling fin that is adjacent in each case.

By enhancing the existing cooling fins with further cooling fins, it is possible to subsequently augment the cooling power of the power module unit.

In a further advantageous embodiment of the invention, the cooling fin is embodied from carbon, for example from graphite, at least in regions.

Advantageously, the cooling fin may be embodied from carbon nanotubes or comprise carbon nanotubes, at least in regions.

In particular, graphite or carbon nanotubes have a particularly high thermal conductivity.

Due to the high thermal conductivity, the cooling of the base plate can be improved.

In a further advantageous embodiment of the invention, cooling fins are connected to one another.

The connection of the cooling fins advantageously takes place by way of connecting elements. The connecting elements and the cooling fins preferably form a unit. The unit is advantageously introduced into the recesses in the base plate as a whole.

Preferably, the connecting elements are connected to the cooling fins with a material fit.

Preferably, the cooling fins and the connecting elements are designed in an integral manner. The connecting elements preferably have openings. Advantageously, the openings serve to reduce weight. The openings are further preferably embodied for passing a cooling medium through, in particular a flow of cooling air

By way of the unit, a particularly fixed and uniform connection of the cooling fins to the base plate is possible. Moreover, heat can be transferred from one cooling fin to another cooling fin.

In an advantageous embodiment of the invention, cooling fins are connected to one another using connecting elements to form a unit. Preferably, the units are shaped such that a unit can be connected to a further unit by a plug-in connection, a pressed connection or an adhesive connection.

The unit preferably has cooling fins oriented in parallel, wherein cooling fins are connected to one another by the connecting elements.

Preferably, the cooling fins have a structured surface at both ends, in particular a corrugated surface. By way of the structured surface, an improved connection of the cooling fins to one another is possible, wherein for connection purposes a cooling fin is preferably plugged between two other cooling fins in each case. The structured surface serves for the improved cohesion of the cooling fins among one another. The cooling fins are fixed to one another by the connecting elements.

An advantageous application of the power module unit described here is a frequency converter or power supply, in particular for industrial use.

Advantageously, such a frequency converter serves for mobile applications such as at least partially electrically driven vehicles. The invention can further advantageously be used in electrically driven aircraft. In addition, the invention can advantageously be used for a charging device. Preferably, the invention finds use in a charging device for an electrically driven vehicle or aircraft.

Advantageously, the type, number, shape and size of the cooling fins can be selected according to the cooling requirement of the power module unit in the respective application.

In the method for producing a power module unit, the power module unit has a base plate with recesses on a first side, comprising the following steps:

a) positioning a substrate on a second side opposite the recesses;
b) heating the base plate and the substrate, so that the substrate is fastened to the first side of the base plate, in particular by way of a soldered, sintered or pressed connection;
c) introducing and fastening at least one cooling fin in the respective recess, wherein the fastening is designed with a positive fit and/or non-positive fit.

Optional and advantageous steps during the production of the power module unit are:
fastening a housing to the base plate, wherein the housing protects the substrate and a power semiconductor;
attaching contact elements to a metal layer, wherein the metal layer serves to fasten the power semiconductor. The respective contact element may be connected to the housing on one side. The contact element advantageously serves to link the power semiconductor to an electrical line.
Preferably, the substrate is insulated. An insulation advantageously takes place by applying a non-conductive polymer-based material, in particular silicone-based material, to the substrate.

Preferably, the heating of the base plate with the substrate takes place in a furnace. The substrate and the base plate are heated to a temperature between 200 and 500 degrees Celsius. The heating serves to embody a soldered, sintered or pressed connection of the substrate to the base plate.

The cooling fins are preferably introduced together into a recess provided for the cooling fin in each case. The cooling fins are oriented and the base plate forced on for this purpose.

In an advantageous embodiment, the recesses are introduced into the base plate after fastening the substrate.

Preferably, the recesses are introduced into the base plate by way of machining. By introducing the recess subsequently, the base plate can be heated in a furnace without having recesses. Due to the cuboid-shaped design of the base plate, it is possible for the base plate to be heated in a particularly uniform manner and to be embodied in a particularly stable manner in the case of a pressed connection of the base plate to the substrate.

In order to embody a non-positive connection, the material of the base plate and the material of the respective cooling fin may be selected in such a way that, in the case of a heated base plate, the cross-section of the recess in the base plate is enlarged and, at room temperature around the part of the cooling fin that is situated in the recess, embodies a non-positive and/or positive connection.

As an alternative or in addition, a soldered connection or an adhesive connection may also contribute to fastening the respective cooling fin to the base plate.

By way of the method described above for producing the power module unit the cooling fins may be selected according to the respective use. At the same time, time is saved when connecting the base plate to the substrate, because the cooling fins do not also have to be heated. Additionally, by heating the base plate without cooling fins, a particularly uniform temperature distribution is possible, which leads to an improved soldered or sintered connection of the substrate to the base plate.

Moreover, the height of the furnace advantageously can be embodied as particularly low.

in a further advantageous embodiment of the invention, the heating of the base plate with the substrate takes place in a furnace.

The heating of the base plate and the substrate on the base plate preferably takes place in a continuous furnace. By simply modifying the throughput time of the base plates through the furnace, the necessary heating of the base plate and the substrate can be set in an effective manner.

In a further advantageous embodiment of the invention, the introduction of the cooling fin into the recess takes place after the base plate is cooled down.

Preferably, the base plate is cooled down to room temperature before the cooling fin is introduced. By cooling down the base plate, the protrusions in the recess are prevented from warping when a cooling fin is introduced. In addition, an improved hold is possible when adhesively bonding the cooling fins to the base plate.

In a further advantageous embodiment of the invention, the cooling fins are introduced into the respective recess along the recess.

In order to protect the substrate when introducing the cooling fin into the recess, force that leads to a bending of the base plate should be avoided. As the base plate is more stable along the tangential direction in relation to the sides, an introduction of the at least one cooling fin in the tangential direction leads to a low deformation of the base plate and thus to a low strain on the substrate.

In a further advantageous embodiment of the invention, the respective cooling fin comprises an opening, wherein a pressing means is guided into the opening of the cooling fin and the cooling fin is pressed into the recess with the aid of the pressing means.

Depending on the shape of the pressing means and a cross-section of the cooling fin, the pressing means may contribute to embodying a positive connection. The pressing means preferably deforms the respective end of the cooling fin, so that the material of the cooling fin fills the recess, at least in regions.

A rod can be used as pressing means. The pressing means is preferably guided through an opening of the cooling fin and the cooling fin is introduced into the recess. By using a pressing means that acts on the cooling fin in the vicinity of the recess, it is possible for a warping of the cooling fin to be effectively prevented.

In a further advantageous embodiment of the invention, the base plate has copper, aluminum or a layer of copper and a layer of aluminum and/or the respective cooling fin has copper, aluminum or an alloy.

In a further advantageous embodiment of the invention, the heating of the base plate with the substrate takes place in a furnace and/or the introduction of the cooling fin into the recess takes place after the base plate has cooled down.

In a further advantageous embodiment of the invention, the cooling fins that are provided for introduction into the recesses of the base plate are, in one step, introduced into the recess provided for the cooling fin in each case.

In a further advantageous embodiment of the invention, the introduction of the at least one cooling fin takes place tangentially in relation to the first side of the base plate, wherein the recess has a cross-section that in particular is embodied in a trapezoid-shaped manner. Preferably, all cooling fins are introduced into the base plate in such a manner.

In a further advantageous embodiment of the invention, when introducing the at least one cooling fin into the base plate tangentially, the at least one cooling fin is slid into the recess orthogonally in relation to the cross-section of the recess, so that in particular the base plate is only minimally deformed. Preferably, all cooling fins are slid into the base plate in such a manner.

In a further advantageous embodiment of the invention, the at least one cooling fin is introduced into the recess, in particular slid in or drawn in, via a side area of the base plate which is oriented orthogonally in relation to the side area.

The at least one cooling fin is consequently slid or drawn into the recess starting from the side area of the base plate, so that, during the introduction of the at least one cooling fin into the recess, the recess is covered by the at least one cooling fin in a step-by-step manner when viewing the first side of the base plate. Preferably, all cooling fins are slid or drawn into the base plate in such a manner.

The invention will now be described and explained in greater detail making reference to the figures. The embodiments shown in the figures are merely exemplary and do not limit the invention. Individual features of the exemplary embodiments may be combined to form further new embodiments of the invention.

In the figures:

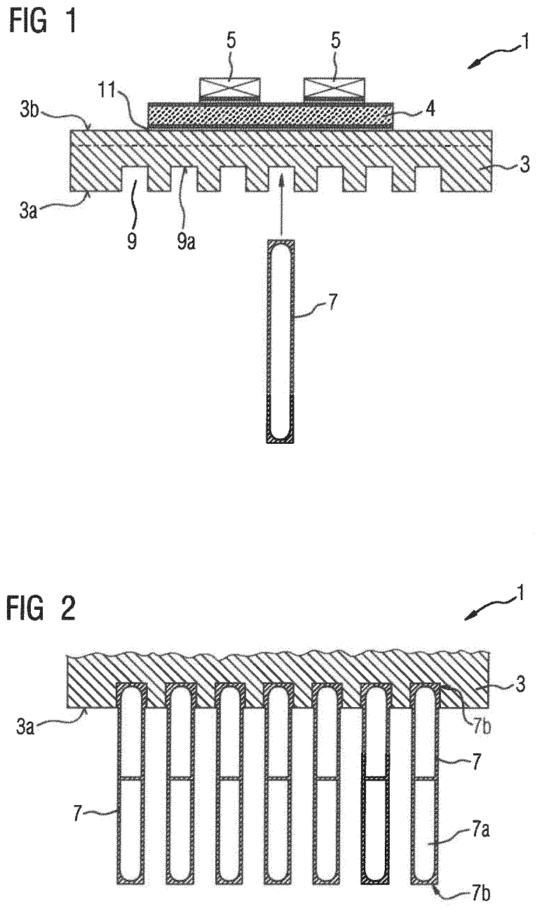

FIG. 1 shows an exemplary power module unit,

FIG. 2 shows a cutout of an exemplary power module unit,

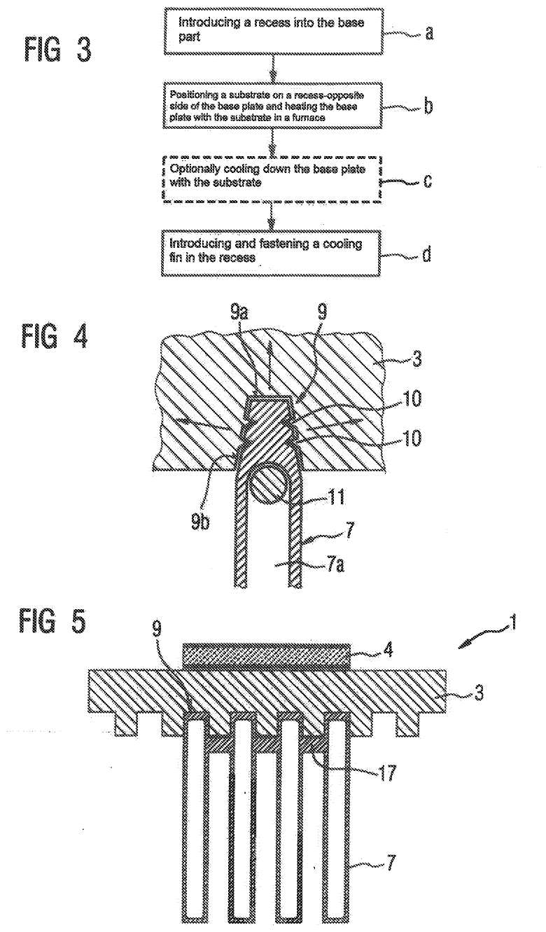

FIG. 3 shows an exemplary method,

FIG. 4 shows a possible cross-section of a recess,

FIG. 5 shows a further exemplary power module unit,

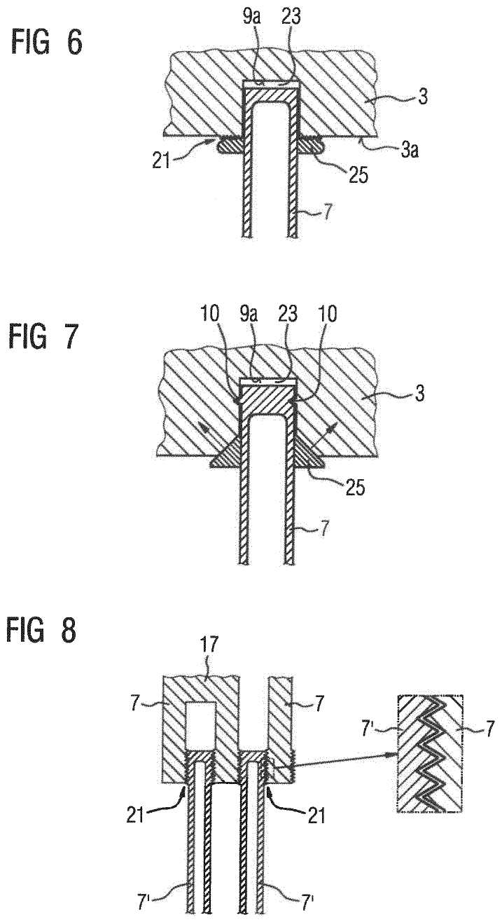

FIG. 6 shows a cutout of a power module unit,

FIG. 7 shows a cutout of a power module unit, and

FIG. 8 shows a connection between cooling fins and further cooling fins.

FIG. 1 shows an exemplary power module unit 1. The power module unit 1 comprises a base plate 3, wherein the base plate 3 has recesses 9 on a first side. The recesses 9 serve to accommodate at least one cooling fin 7 in each case. The base plate has a substrate 4 on a second side 3b. The substrate 4 serves as a carrier for the power semiconductor 5. The substrate is preferably produced from a ceramic, wherein the substrate has a copper coating on both sides. The copper coating serves in particular as a basis for a soldered connection 11 for fastening the substrate 4 to the base plate 3. The power semiconductors 5 are preferably likewise connected to the substrate 4 by a soldered connection 11.

The base plate 3 is preferably embodied from a copper ahoy or an aluminum alloy. Particularly advantageously, the base plate 3 is produced from aluminum in the lower region adjoining the first side 3a, and is produced from copper in the upper region adjoining the second side 3b. The basis for such a base plate 3 is a layered material. One possible layered structure is indicated by the dashed line in the base plate 3.

The respective cooling fin is fastened into the respective recess 9 in the base plate 3 by way of a positive and/or non-positive connection using the base plate 3.

FIG. 2 shows a cutout of an exemplary power module unit 1. A base plate 3 is shown with a plurality of cooling fins 7. The cooling fins 7 are introduced in one of the recesses 9 of the base plate 3 in each case. The cooling fins 7 shown each have two openings 7a. The openings 8 are separated from one another by a border in the center of the cooling fin 7. An 8-shaped profile of the cooling fin is therefore embodied. Due to the 8-shaped profile, a flow of air is able to cool the cooling fins in a particularly efficient manner.

At the respective end 7b of the cooling fin 7, the cooling fin 7 is embodied in a reinforced manner. Such a reinforcement may be achieved by an increased wall thickness of the cooling fin 7 in the region of the respective end 7a thereof. By reinforcing the cooling fin 7 at its respective end 7a, a particularly stable connection of the respective cooling fin 7 to the base plate 3 is possible.

FIG. 3 shows an exemplary method. The method comprises a first step a, a second step b, a third, optional step c and a fourth step d.

In the first step a, the respective recess 9 is introduced into the base plate 3. The recess is imprinted into the base plate by a rolling process, a machining method such as milling or by a forging method.

In a second step b, a substrate 4 is positioned on the second side 3b of the base plate 3. To fasten the substrate 4 to the second side 3b of the base plate 3, the base plate with the substrate is heated in a furnace to a temperature of 200 degrees to 500 degrees Celsius. The substrate 4 is connected to the second side 3b of the base plate in a fixed manner in the second step b by way of a soldered connection or a sintered connection.

In a third, optional step c, the base plate with the substrate is cooled down to room temperature again. Depending on the type of connection of the substrate 4 to the base plate 3, the cooling down takes place rapidly or slowly.

In a fourth step d, the cooling fins 7 are introduced into the respective recess 9 of the base plate and fastened. The introduction of the cooling fins takes place either from the side, i.e. tangentially in relation to the first side 3a of the base plate 3, or perpendicularly in relation thereto. When introducing the cooling fins 7 into the base plate tangentially, the cooling fin 7 is slid into the recess orthogonally in relation to the cross-section 9a of the recess 9. Such an introduction advantageously only minimally deforms the base plate.

When introducing the respective cooling fin 7 into the recess 9 perpendicularly, care should be taken that the force that acts on the base plate 3 does not lead to a deformation of the base plate 3, as otherwise the substrate 4 could be damaged.

FIG. 4 shows a possible cross-section 9a of a recess 9. The recess 9 in the base plate 3 is inwardly tapered. For improved holding of the cooling fin 7, the recess 9 has protrusions 10 on its inner side 9b. The protrusions 10 advantageously serve to embody positive connections in regions between the base plate 3 (shown as a cutout here) and the cooling fin 7.

The trapezoid-shaped cross-section 9a of the recess 9, when introducing the cooling fin 7 into the recess 9 in a perpendicular manner, serves to reduce the force that acts perpendicularly in relation to the first side 3a or second side 3b of the base plate 3. Instead, the force is redirected in a direction running tangentially in relation to the respective side 3a,3b of the base plate 3. This is represented by the arrows that emerge from the recess.

Moreover, a pressing means 11 is indicated in the figure. The pressing means 11 serves to introduce the cooling fin 7 into the recess 9. Preferably, the pressing means 11 is designed as a rod, which is guided through the opening 7a of the cooling fin and is able to press the cooling fin 7 into the recess 9 of the base plate 3. Depending on the shape of the pressing means 11 and a cross-section of the cooling fin 7, the pressing means 11 may contribute to embodying a positive connection. The pressing means 11 preferably deforms the respective end 7a of the cooling fin 7, so that the material of the cooling fin 7 fills the recess 9, at least in regions.

FIG. 5 shows a further exemplary power module unit 1. The power module unit 1 has a similar structure to the power module unit that is shown in FIG. 1. Unlike in FIG. 1, the power module unit 1 shown here comprises cooling fins 7 that are connected to one another. The connection of the cooling fins takes place by way of connecting elements 17. The connecting elements 17 and the cooling fins 7 form a fixed unit here. The unit consisting of cooling fins 7 and connecting elements 17 is introduced into the recesses 9 in the base plate 3, where it is connected to the base plate with a positive fit and/or a non-positive fit, at least in regions.

FIG. 6 shows a cutout of a power module unit 1. A cutout of the base plate 3 with the recess 9 is shown, wherein a cooling fin 7 has been introduced into the recess 9. The cooling fin 7 comprises an attachment 25, wherein the attachment 25 is positioned on the respective side of the cooling fin 7 such that, once the cooling fin 7 has been introduced into the recess 9, a cavity 23 is embodied in the recess. The cavity 23 is arranged between the side of the cooling fin 7 and the bottom side of the recess 9. The cavity 23 is embodied because the cooling fin is not fully introduced into the recess 9. In order to embody the cavity 23, the respective attachment 25 is positioned on the sides of the cooling fin 7 in such a manner that, once the cooling fin 7 has been introduced into the recess 9, the attachment 25 touches the first side 31 or is fastened thereto.

Advantageously, the attachment 25 of the cooling fin 7 is in contact with the first side 3a of the base plate 3. Advantageously, the attachment 25 being in contact with the first side 3a increases a planar connection 21 between cooling fin 7 and the base plate. The planar connection serves to transfer heat from the base plate 3 to the cooling fin.

The height of the cavity 23 may also be embodied as being small enough for the bottom side of the recess 9 to touch the cooling fin 7 at points.

FIG. 7 shows a cutout of a power module unit 1. In a similar way to the cutout that is shown in FIG. 6, the cooling fin 7 likewise has an attachment 26. The attachment 25 is embodied such that it has an oblique contact area, wherein the oblique contact area is in contact with a corresponding oblique area in the recess 9. When introducing the cooling fin 7 into the recess 9, the forces that occur are marked by arrows. The forces (symbolized by the arrows) have, as a function of the orientation of the oblique contact area, a force component in the parallel direction to the first side of the base plate 3.

Due to the oblique orientation of the contact area, when introducing the cooling fin 7, less force is impressed onto the base plate 3 to embody a bending stress and therefore to impose strain on the substrate 4. Moreover, the area between the cooling fin 7 and the base plate 3 is enlarged. Due to the enlarged area, heat can be emitted from the base plate 3 to the cooling fin.

For the improved connection of the cooling fin 7 to the base plate, the inner side 9a of the recess 9 and/or the cooling fin 7 have a protrusion 10 on their side. The protrusion preferably protrudes into a notch, wherein the notch is introduced in each case on the side that touches the protrusion. Preferably, such a protrusion 10 contributes to the improved stability of the connection between the base plate 3 and the cooling fin 7.

FIG. 8 shows a connection 21 between cooling fins 7 and further cooling fins 7′. The connection 21 between the cooling fins 87 and the further cooling fins 7′ may be embodied by a damped connection or a non-positive connection. For improved cohesion, the cooling fins 7 and/or the further cooling fins 7′ have a corrugated structure in the region of the connection 21. Preferably, cooling fins 7 and/or further cooling fins 7′ have protrusions with a triangle cross-section that extend in parallel in regions on their respective side. These protrusions may also protrude into notches, wherein the notches have a triangular cross-section and are positioned in the cooling fin 7 and/or the further cooling fin 7′ between the protrusions. One such connection 21 is shown in the enlarged view. The corrugated structure serves to connect the cooling fins 7 to the respective further cooling fin 7′ in a more stable manner.

A connecting element 17 is shown, wherein the connecting element 17 reveals the possibility of connecting the cooling fins 7 (similarly to the embodiment shown in FIG. 5).

The further cooling fins 7′, which are introduced into the intermediate spaces of the cooling fins 7 which are oriented in parallel in each case, serve to further improve the cooling of cooling fins 7 embodied in parallel in each case and thus serve to cool the substrate 4 on the base plate 3 in an improved manner

In summary, the invention relates to a method for producing a power module unit 1 and to a power module unit 1. Moreover, the invention relates to a power supply and to a frequency converter. In order to produce the power module unit 1, a base plate 3 is provided with recesses 9. The base plate is connected to a substrate 4, which carries the power semiconductor 5. After fastening the substrate 4 to the base plate, the cooling fins 7 are guided into the recesses 9 in the base plate 3 and are fastened with a positive and/or non-positive fit. Due to the embodiment, a power module unit 1 may be embodied with cooling fins 7 as required, and at the same time the production of the power module unit 1 may be simplified.

What is claimed:

1.-18. (canceled)

19. A power module unit, in particular for a frequency converter, said power module comprising:
a base plate having a first side provided with a recess and a second side;
a cooling fin fastened in the recess of the base plate at least in one region by at least one connection selected from the group consisting of a positive fit, a material fit, and a non-positive fit; and
a substrate for a power semiconductor, said substrate being disposed on the second side of the base plate.

20. The power module unit of claim 19, wherein the connection of the cooling fin to the base plate is a pressed connection, an adhesive connection, or a soldered connection.

21. The power module unit of claim 19, wherein the base plate includes copper, aluminum or a layer of copper and a layer of aluminum and/or the cooling fin includes copper, aluminum or an alloy thereof.

22. The power module unit of claim 19, wherein the cooling fin includes an attachment such as to touch the first side of the base plate when the cooling fin is received in the recess.

23. The power module unit of claim 19, wherein one of the base plate and the cooling fin has a notch and another one of the base plate and the cooling fin has a protrusion to reinforce the connection of the cooling fin to the base plate.

24. The power module unit of claim 19, wherein the base plate is made of a material having a hardness which is different than a hardness of a material for the cooling fin.

25. The power module unit of claim 19, wherein the cooling fin has a U-shaped configuration, O-shaped configuration, or an 8-shaped configuration.

26. The power module unit of claim 19, wherein the recess has a cross-section which is tapered toward the second side, preferably is embodied in a trapezoid-shaped manner.

27. The power module unit of claim 19, further comprising a plurality of said cooling fin and a further cooling fin positioned between adjacent two of the plurality of said cooling fin such that the further cooling fin and the adjacent two of the plurality of said cooling fin have at least one region with overlapping sides,

28. A frequency converter or power supply, in particular for industrial use, comprising a power module unit, said power module unit comprising a base plate having a first side provided with a recess and a second side, a cooling fin fastened in the recess of the base plate at least in one region by at least one connection selected from the group consisting of a positive fit, a material fit, and a non-positive fit in regions, and a substrate for a power semiconductor, said substrate being disposed on the second side of the base plate.

29. A method for producing a power module unit, said method comprising:
forming a recess on a first side of a base plate;
positioning a substrate on a second side of the base plate in opposition to the first side;
heating the base plate and the substrate sufficient to fasten the substrate to the second side of the base plate, in particular by way of a soldered or sintered connection; and
introducing and fastening a cooling fin in the recess by a positive fit and/or non-positive fit.

30. The method of claim 29, wherein the base plate and the substrate are heated in a furnace and/or wherein the cooling fin is introduced into the recess after the base plate has cooled down.

31. The method of claim 29, wherein the cooling fin is introduced into the recess in a direction along the recess.

32. The method of claim 29, wherein a plurality of cooling fins are introduced in one step into a plurality of recesses in the first side of the base plate in one-to-one correspondence.

33. The method of claim 29, wherein the cooling fin is introduced into the recess tangentially in relation to the first side of the base plate, and further comprising shaping the recess in the first side of the base plate with a trapezoidal cross-section.

34. The method of claim 32, wherein the cooling fin is slid into the recess orthogonally in relation to the cross-section of the recess, as the cooling fin is introduced into the recess tangentially in relation to the first side of the base plate to cause minimal deformation of the base plate.

35. The method of claim 29, wherein the cooling fin is introduced into the recess, in particular slid in or drawn in, via a side area of the base plate in orthogonal orientation in relation to the side area.

36. The method of claim 29, further comprising:
forming the cooling fin with an opening, and
guiding a press into the opening of the coaling fin to press the cooling fin into the recess.
